(19) United States
(12) Patent Application Publication
(10) Pub. No.: US 2026/0181774 A1
(43) Pub. Date: Jun. 25, 2026

(54) ELECTRONIC DEVICE AND MANUFACTURING METHOD THEREOF

(71) Applicant: InnoLux Corporation, Miao-Li County (TW)

(72) Inventors: Chia-Ping TSENG, Miao-Li County (TW); Hung-Wen LI, Miao-Li County (TW)

(73) Assignee: InnoLux Corporation, Miao-Li County (TW)

(21) Appl. No.: 19/398,004

(22) Filed: Nov. 23, 2025

Related U.S. Application Data
(60) Provisional application No. 63/737,805, filed on Dec. 23, 2024.

(30) Foreign Application Priority Data
Aug. 13, 2025 (CN) 202511128823.7

(51) Int. Cl. H05K 1/11; H01L 21/48; H01L 23/538; H05K 3/38; H05K 3/40

(52) U.S. Cl. CPC H05K 1/113; H05K 3/386; H05K 3/4061; H05K 2201/09563; H10W 70/095; H10W 70/611; H10W 70/635

(57) ABSTRACT

A manufacturing method of an electronic device includes: providing a substrate having a first surface and a second surface opposite to the first surface; forming a through hole penetrating the substrate, a side wall of the through hole being connected with the first surface and the second surface; forming a first protective layer on the first surface, the second surface and the side wall; forming a conductive layer on the first protective layer such that a portion of the conductive layer is disposed in the through hole; performing a thinning step to remove another portion of the conductive layer; and performing an inspection on the substrate to obtain a thickness variation value of the substrate, the thickness variation value being less than or equal to 20 micrometers.

### CROSS REFERENCE TO RELATED APPLICATION

This application claims the benefit of U.S. Provisional Application No. 63/737,805, filed on Dec. 23, 2024. The content of the application is incorporated herein by reference.

### BACKGROUND OF THE DISCLOSURE

### 1. Field of the Disclosure

The present disclosure relates to an electronic device and a manufacturing method thereof, and more particularly to a manufacturing method of an electronic device including forming a through hole in the substrate and an electronic device manufactured by the method.

### 2. Description of the Prior Art

In the existing electronic device, a through hole may be formed in the substrate, and a conductive material is disposed in the through hole to serve as a conducting wire for transmitting an electrical signal. However, as the size of the through hole becomes smaller and smaller, and the depth-width ratio and density thereof become higher and higher, the stress matching problem easily occurs between the layers formed on the substrate due to the different thermal expansion coefficients of their constituent materials, which may cause the substrate to crack after being heated during the manufacturing process, or result in poor product reliability or yield.

### SUMMARY OF THE DISCLOSURE

One of objectives of the present disclosure is to provide a manufacturing method of an electronic device and an electronic device manufactured by the method, wherein by forming a first protective layer on the side wall of the through hole in the substrate, the stress matching problem between layers may be alleviated, thereby reducing the probability of substrate cracking.

An embodiment of the present disclosure provides a manufacturing method of an electronic device. The method includes: providing a substrate, wherein the substrate has a first surface and a second surface opposite to the first surface; forming a through hole penetrating the substrate, wherein a side wall of the through hole is connected with the first surface and the second surface; forming a first protective layer on the first surface, the second surface and the side wall; forming a conductive layer on the first protective layer such that a portion of the conductive layer is disposed in the through hole; performing a thinning step to remove another portion of the conductive layer; and performing an inspection on the substrate to obtain a thickness variation value of the substrate, wherein the thickness variation value is less than or equal to 20 micrometers.

An embodiment of the present disclosure provides a manufacturing method of an electronic device. The method includes: providing a substrate, wherein the substrate has a first surface and a second surface opposite to the first surface; forming a through hole penetrating the substrate, wherein a side wall of the through hole is connected with the first surface and the second surface; forming a first protective layer on the first surface, the second surface and the side wall; inspecting a first thickness of the first protective layer on the first surface and a second thickness of the first protective layer on the side wall, and determining whether a ratio of the second thickness to the first thickness is greater than or equal to 0.001 and less than or equal to 0.15; forming a conductive layer on the first protective layer such that a portion of the conductive layer is disposed in the through hole; and performing a thinning step to remove another portion of the conductive layer.

Another embodiment of the present disclosure provides an electronic device. The electronic device includes a substrate, a first protective layer and a conductive layer. The substrate has a first surface, a second surface and a through hole, and a side wall of the through hole is connected with the first surface and the second surface. The first protective layer is disposed on the side wall of the through hole, and the conductive layer is disposed in the through hole. A thickness variation value of the substrate is less than or equal to 20 micrometers.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a flowchart of a manufacturing method of an electronic device according to an embodiment of the present disclosure.

FIG. 2 to FIG. 4 are schematic diagrams illustrating a portion of the process of a manufacturing method of an electronic device according to a first embodiment of the present disclosure.

FIG. 5 is a cross-sectional schematic diagram of an electronic device according to an embodiment of the present disclosure.

FIG. 6 is an enlarged cross-sectional schematic diagram of a region AR shown in FIG. 5.

FIG. 7 is a schematic diagram illustrating a portion of the process of a manufacturing method of an electronic device according to a second embodiment of the present disclosure.

FIG. 8 is an enlarged schematic diagram of some variant embodiments of a region CR shown in FIG. 7.

FIG. 9 is a schematic diagram illustrating a portion of the process of a manufacturing method of an electronic device according to a third embodiment of the present disclosure.

FIG. 10 is a schematic diagram illustrating a portion of the process of a manufacturing method of an electronic device according to a fourth embodiment of the present disclosure.

FIG. 11 is a schematic diagram illustrating a portion of the process of a manufacturing method of an electronic device according to a fifth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device or structure, and certain components in various drawings may not be drawn to scale. In addition, the number and dimension of each component shown in drawings are only illustrative and are not intended to limit the scope of the present disclosure.

Certain terms are used throughout the description and following claims to refer to particular components. As one skilled in the art will understand, electronic equipment manufacturers may refer to a component by different names. The present disclosure does not intend to distinguish between components that differ in name but not function. In the following description and in the claims, the terms “include”, “comprise” and “have” are used in an open-ended fashion, and thus should be interpreted to mean “include, but not limited to . . . ”. When the terms “include”, “comprise” and/or “have” are used in the description of the present disclosure, the corresponding features, areas, steps, operations and/or components would be pointed to existence, but not limited to the existence or addition of one or a plurality of the corresponding or other features, areas, steps, operations, components and/or combinations thereof.

When an element or layer is referred to as being “on” or “connected to” another element or layer, it may be directly on or directly connected to the other element or layer, or intervening elements or layers may be presented (indirect condition). In contrast, when an element is referred to as being “directly on” or “directly connected to” another element or layer, there are no intervening elements or layers presented.

The directional terms mentioned in the present disclosure, such as “up”, “down”, “front”, “back”, “left”, “right”, etc., are only directions referring to the drawings. Therefore, the directional terms used are for illustration, not for limitation of the present disclosure.

The terms “about”, “equal”, “identical” or “the same”, and “substantially” or “approximately” mentioned in the present disclosure generally mean being within 20% of a given value or range, or being within 10%, 1% or 0.5% of a given value or range.

The term “between a value A and a value B” is interpreted as including the value A and the value B or including at least one of the value A and the value B, and including other values between the value A and the value B.

In the present disclosure, the thickness, length, width, and/or the distance between components may be measured by using an X-ray diffractometer (XRD), an optical microscope (OM), an electron microscope (such as a scanning electron microscope (SEM), a transmission electron microscope (TEM), etc.) or other methods, but not limited herein.

In the present disclosure, the roughness may be determined by observing through a SEM. On an uneven surface, the difference in distance between the peaks and valleys of the surface undulations may be defined as the roughness of the uneven surface. The measurement of the roughness determination may include observing surface undulations using instruments such as a SEM, a TEM and the like at the same appropriate magnification, and taking a sample with a unit length (e.g., 10 micrometers) to compare the undulation condition as its roughness range. The term “appropriate magnification” described above refers to a magnification at which at least 10 undulating peaks of a roughness (Rz) or an average roughness (Ra) of at least one surface can be seen within the field of view.

The ordinal numbers used in the description and claims, such as “first”, “second”, “third”, etc., are used to describe elements, but they do not mean and represent that the element(s) have any previous ordinal numbers, nor do they represent the order of one element and another element, or the order of manufacturing methods. The ordinal numbers are used only to clearly discriminate an element with a certain name from another element with the same name. The claims and the description may not use the same terms. Accordingly, in the following description, a first constituent element may be a second constituent element in a claim.

The electronic device of the present disclosure may applied to a high performance computing, a semiconductor package device, a display device, a light-emitting device, a backlight device, an antenna device, a sensing device, a tiled device or other suitable devices, but not limited herein. The electronic device may include electronic elements such as semiconductor elements including passive elements and active elements, such as capacitors, resistors, inductors, diodes, transistors, integrated circuits, etc. The semiconductor element may include a semiconductor layer or an electronic element manufactured by a semiconductor process, but not limited herein. The electronic device may include peripheral systems such as a driving system, a controlling system, a light source system, a shelving system, and the like. The outline of the electronic device may be a rectangle, a circle, a polygon, a shape with curved edge, curved or other suitable shapes. It should be noted that the electronic device of the present disclosure may be any combination of the above devices, but not limited herein.

The manufacturing method of the electronic device of the present disclosure may for example be applied to a wafer-level package (WLP) process or a panel-level package (PLP) process, wherein the WLP process or the PLP process may include a chip-first process or a chip-last process, but not limited herein. The electronic device may include the system on a chip (SoC), system in a package (SiP), antenna in package (AiP), co-packaged optics (CPO) or combinations of the above devices, but not limited herein.

It should be noted that the technical features in different embodiments described in the following can be replaced, recombined, or mixed with one another to constitute another embodiment without departing from the spirit of the present disclosure.

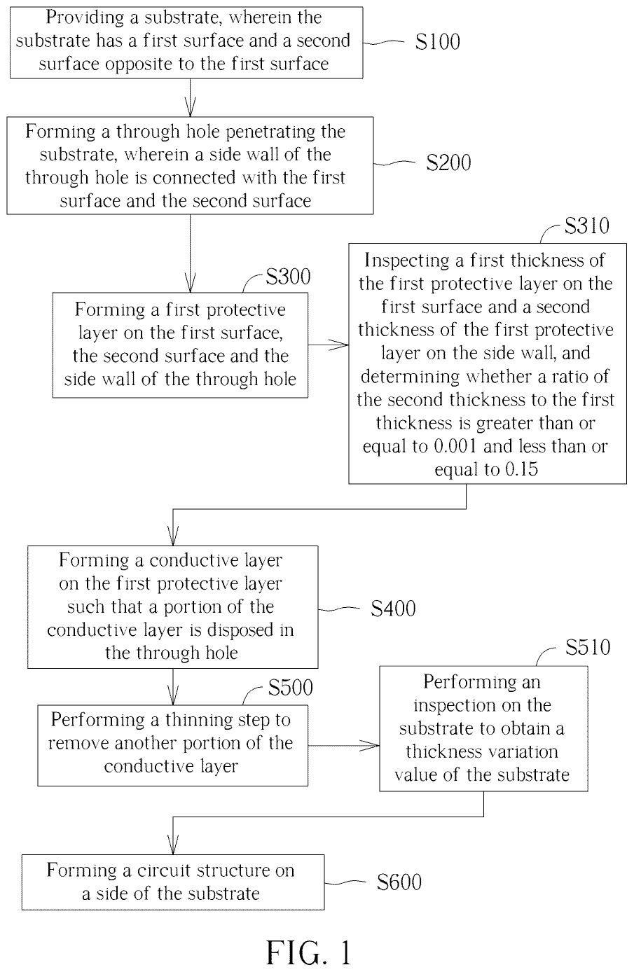

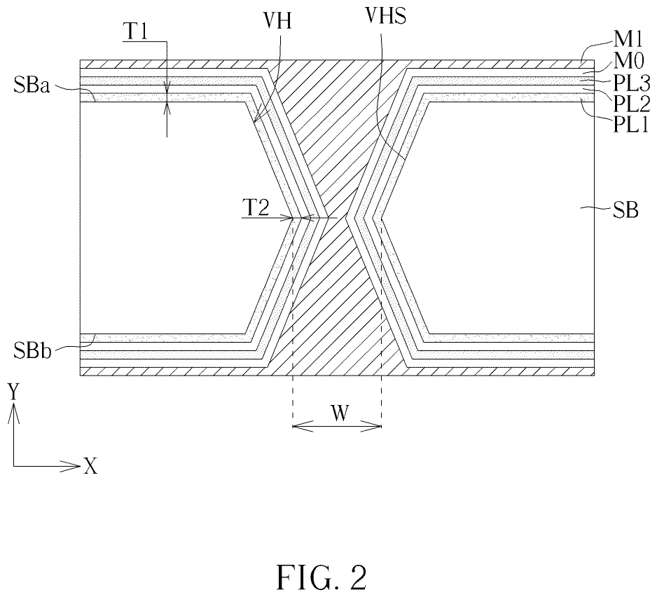

Please refer to FIG. 1 and FIG. 2 to FIG. 4. FIG. 1 is a flowchart of a manufacturing method of an electronic device according to an embodiment of the present disclosure. FIG. 2 to FIG. 4 are schematic diagrams illustrating a portion of the process of a manufacturing method of an electronic device according to a first embodiment of the present disclosure. As shown in FIG. 1, a manufacturing method of an electronic device according to an embodiment of the present disclosure may include Step S100, Step S200, Step S300, Step S400 and Step S500, and the manufacturing method of the electronic device of the present disclosure may further include other steps before, after or during any of the above steps. As shown in FIG. 1, in some embodiments, the method may further include Step S310, Step S510 and/or Step S600. The details of each step in the manufacturing method of the electronic device of the present disclosure will be described below with reference to FIG. 2 to FIG. 4.

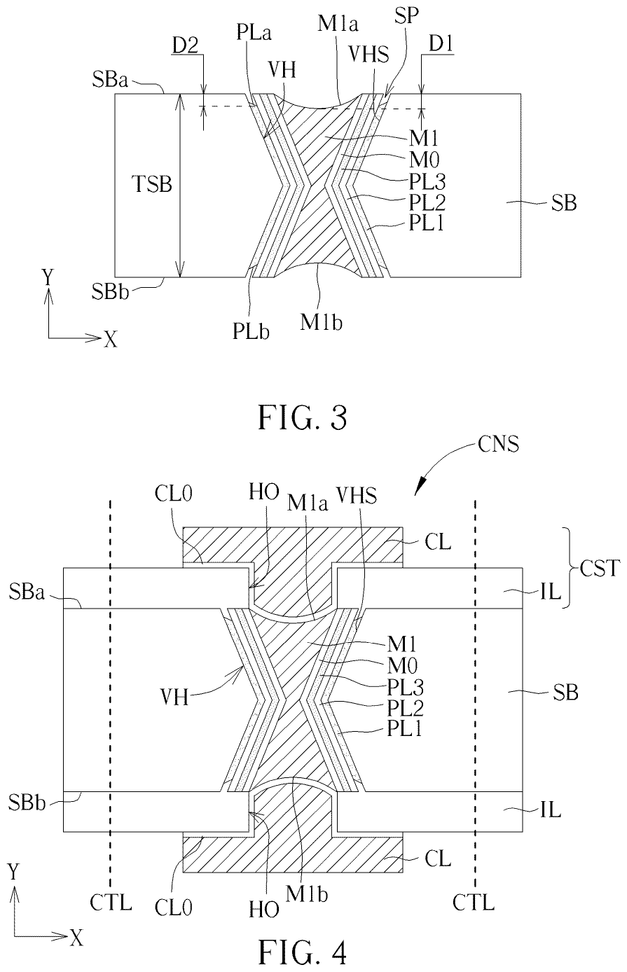

Specifically, as shown in FIG. 2, first, Step S100 may be performed to provide a substrate SB, wherein the substrate SB has an upper surface SBa (which may be referred to as a first surface) and a lower surface SBb (which may be referred to as a second surface) opposite to the upper surface SBa. The substrate SB may include a glass substrate, a transparent material including silicon, an optical layer, an acrylic board, a semiconductor structure substrate, combinations of the above or other transparent materials, and the substrate SB may have certain stiffness and insulation. That is to say, the stiffness of the substrate SB may be greater than the stiffness of a circuit structure (such as the circuit structure CST shown in FIG. 4 or FIG. 5) formed on the substrate SB, for example, the stiffness of the substrate SB is greater than the stiffness of an insulating layer of the circuit structure, so that the warpage may be mitigated when the substrate SB is used for carrying the circuit structure, but not limited herein. The “stiffness” referred to in the present disclosure may be tested by a universal testing machine (UTM). In some embodiments, the thermal expansion coefficient of the substrate SB may be greater than or equal to 1 ppm/° C. and less than or equal to 10 ppm/° C., thereby improving the support of the substrate SB or further improving the reliability of the electronic device. In some embodiments, the transmittance of the substrate SB for visible light may be at least greater than or equal to 80%. In some embodiments, the thickness of one substrate SB may be greater than 40 micrometers (μm) and less than or equal to 1600 micrometers.

After Step S100, Step S200 may be performed to form a through hole VH penetrating the substrate SB, wherein a side wall VHS of the through hole VH is connected with the upper surface SBa and the lower surface SBb of the substrate SB. For example, one or more through holes VH may be formed in the substrate SB by performing a modification process and an etching process on the substrate SB. Specifically, a modification process (e.g., a laser modification process) may be performed on a portion of the substrate SB, wherein the portion of the substrate SB may correspond to a predetermined disposing positions of the through holes VH, and then the substrate SB may be inspected to determine whether these predetermined positions for the through holes have been sufficiently modified. If so, the substrate SB may be determined to be a qualified product. When the substrate SB is determined to be qualified, or after performing the modification process, an etching process (e.g., a dry etching process or wet etching process) may be performed on the substrate SB to remove the modified portion of the substrate SB, thereby forming one or more through holes VH that penetrate the substrate SB. In some embodiments, in a cross-sectional view, the formed through holes VH may have shapes such as hourglass, rectangular, trapezoidal, inverted trapezoidal or other suitable shapes. FIG. 2 to FIG. 4 illustrate the hourglass shape as an example, but the present disclosure is not limited thereto. In some embodiments, after forming the through holes VH (i.e., after the etching process or Step S200), the substrate SB may be inspected to determine whether the structure of the substrate SB with the formed through holes VH is qualified, for example, whether the outline of the through holes VH meets the requirements. When the substrate SB is determined to be qualified, subsequent steps (e.g., Step S300) may be performed. Each of the inspection steps mentioned in the present disclosure may include performing optical inspection by using an optical system, such as (but not limited to) inspecting by an automated optical inspection (AOI) system.

After Step S200, Step S300 may be performed to form a first protective layer PL1 on the upper surface SBa and the lower surface SBb of the substrate SB and the side wall VHS of each through hole VH. The first protective layer PL1 may include at least one of an organic material and an inorganic material. That is to say, the first protective layer PL1 may include an organic material, an inorganic material, or a combination of both. The organic material includes, for example, hydrogenated polymers or hydrogenated silicon oxycarbide (SiOC:H), and the inorganic material includes, for example, silicon oxycarbide (SiOC), but not limited herein. In some embodiments, after forming the first protective layer PL1 (i.e., after Step S300), Step S310 may be performed to inspect a first thickness T1 of the first protective layer PL1 on the upper surface SBa (or the lower surface SBb) of the substrate SB and a second thickness T2 of the first protective layer PL1 on the side wall VHS of the through hole VH, and it is then determined whether a ratio of the second thickness T2 to the first thickness T1 is greater than or equal to 0.001 and less than or equal to 0.15. When the ratio of the second thickness T2 to the first thickness T1 is greater than or equal to 0.001 and less than or equal to 0.15 (i.e., when 0.001≤T2/T1≤0.15, subsequent steps (e.g., Step S400) may be performed. The first thickness T1 may be obtained by measuring the maximum thickness of the first protective layer PL1 in a direction Y on the upper surface SBa (or the lower surface SBb), and the second thickness T2 may be obtained by measuring the minimum thickness of the first protective layer PL1 on the side wall VHS. According to the embodiment shown in FIG. 2, the second thickness T2 may correspond to the thickness of the first protective layer PL1 at the center of the through hole VH. The term “center of the through hole VH” mentioned in the present disclosure may refer to a location at 40% to 60% of the depth of the through hole VH in the direction Y, where the through hole VH has the minimum width W in a direction X. In the present disclosure, the direction Y may be a normal direction of the substrate SB, i.e., the direction Y may be parallel to a normal direction or a top-view direction of the upper surface SBa (or the lower surface SBb) of the substrate SB and may be a normal direction of the manufactured electronic device. The direction X may be perpendicular to the direction Y, and may, for example, be a horizontal direction.

In some embodiments, by measuring and controlling the first thickness T1 of the first protective layer PL1 on the upper surface SBa (or the lower surface SBb) of the substrate SB, the second thickness T2 of the first protective layer PL1 on the side wall VHS of the through hole VH can be made to meet the required standard. For example, when the ratio of the second thickness T2 to the first thickness T1 is predetermined to be 0.1 (i.e., when T2/T1=0.1) based on the process conditions, and the required second thickness T2 is 5 micrometers, the first thickness T1 may be measured and controlled to reach 50 micrometers to ensure the coverage status of the first protective layer PL1 on the side wall VHS of the through hole VH, without the need to additionally measure the second thickness T2.

After Step S300 or Step S310, Step S400 may be performed to form a conductive layer M1 on the first protective layer PL1, such that a portion of the conductive layer M1 is disposed in the through hole VH. For example, the conductive layer M1 may be formed on the first protective layer PL1 and in the through hole VH by electroplating, electroless plating, sputtering, or other suitable processes, so that a portion of the conductive layer M1 is filled in the through hole VH, and another portion of the conductive layer M1 is located on the upper surface SBa and the lower surface SBb of the substrate SB. In some embodiments, as shown in FIG. 2, before forming the conductive layer M1 (i.e., before performing Step S400), a second protective layer PL2, a third protective layer PL3 and/or a seed layer M0 may be formed on the first protective layer PL1. Specifically, after forming the first protective layer PL1, the second protective layer PL2 may be formed on the first protective layer PL1, and the second protective layer PL2 may be disposed on the surface of the first protective layer PL1 and extend into the through hole VH. The toughness of the first protective layer PL1 may be greater than the toughness of the second protective layer PL2, the dissipation factor (Df) of the second protective layer PL2 may be less than the dissipation factor of the first protective layer PL1, and the dielectric constant (Dk) of the second protective layer PL2 may also be less than the dielectric constant of the first protective layer PL1. The second protective layer PL2 may include, for example, an inorganic material, which may be a low dielectric factor and low dielectric constant material. The thickness of the second protective layer PL2 may be greater than or equal to 0.1 micrometers and less than or equal to 5 micrometers. After forming the second protective layer PL2, the third protective layer PL3 may optionally be formed on the second protective layer PL2, and the third protective layer PL3 may extend into the through hole VH. The toughness of the first protective layer PL1 may be greater than the toughness of the third protective layer PL3, the dissipation factor of the third protective layer PL3 may be less than the dissipation factor of the first protective layer PL1, and the dielectric constant of the third protective layer PL3 may be less than the dielectric constant of the first protective layer PL1. The third protective layer PL3 may include at least one of an organic material and an inorganic material, wherein the organic material may include, for example, hydrogenated silicon oxycarbide (SiOC:H), polyimide (PI), photosensitive polyimide (PSPI) or polybenzoxazole (PBO), and the inorganic material may include, for example, silicon oxycarbide (SiOC), but not limited herein. After forming the third protective layer PL3, the seed layer M0 may be formed on the third protective layer PL3, and the seed layer M0 may extend into the through hole VH. Subsequently, Step S400 may be performed to form the conductive layer M1 on the seed layer M0, and the conductive layer M1 is filled in the through hole VH. The seed layer M0 may facilitate the formation of the conductive layer M1 and/or enhance the adhesion between layers. The seed layer M0 may have a single-layer or multi-layer structure, and the material of the seed layer M0 includes, for example, titanium (Ti), titanium nitride (TiN), ruthenium (Ru), tantalum (Ta), silver (Ag), copper (Cu) or combinations of the above.

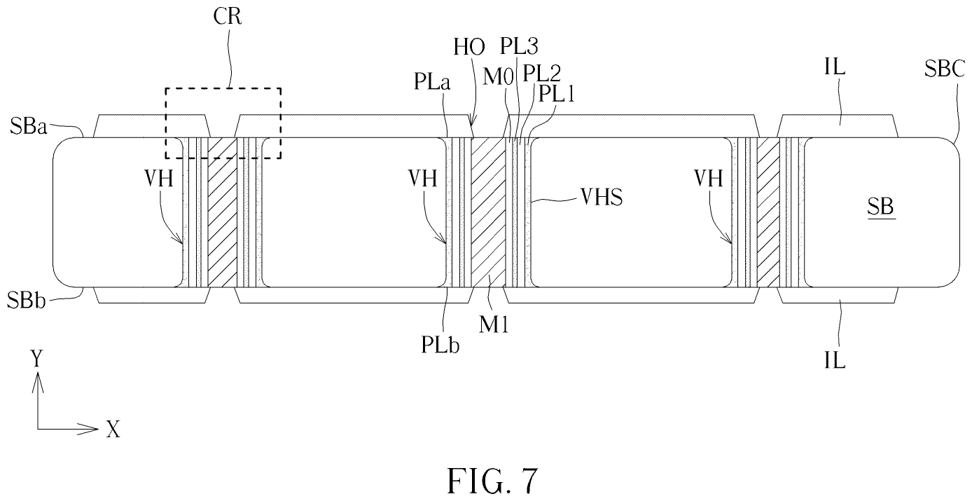

As shown in FIG. 3, after Step S400, Step S500 may be performed to carry out a thinning step to remove another portion of the conductive layer M1. The thinning step may include one of a chemical mechanical polishing (CMP) process or a wet etching process, or may include both of the above processes. Specifically, according to the embodiment shown in FIG. 3, in the thinning step, a portion of the conductive layer M1 disposed outside the through hole VH (i.e., the portion other than the portion disposed in the through hole VH) may be removed, and a portion of the first protective layer PL1, a portion of the second protective layer PL2, a portion of the third protective layer PL3 and a portion of the seed layer M0 may further be removed, such that the layer-stacking structure located on the upper surface SBa and the lower surface SBb of the substrate SB is removed, thereby exposing the upper surface SBa and the lower surface SBb. The conductive layer M1 has an upper surface M1a (which may be referred to as a third surface) and a lower surface M1b opposite to the upper surface M1a after the portion of the conductive layer M1 outside the through hole VH (i.e., the another portion described above) is removed, wherein the upper surface M1a is adjacent to the upper surface SBa of the substrate SB, i.e., the upper surface M1a of the conductive layer M1 is closer to the upper surface SBa of the substrate SB than the lower surface M1b thereof, and the lower surface M1b of the conductive layer M1 is adjacent to the lower surface SBb of the substrate SB. In the direction Y, the maximum height difference between the upper surface SBa of the substrate SB and the upper surface M1a of the conductive layer M1 may be defined as a first height difference D1, wherein the first height difference D1 is less than or equal to 1 micrometer. As shown in FIG. 3, the upper surface M1a of the conductive layer M1 may be recessed relative to the upper surface SBa of the substrate SB, forming a recess such that the upper surface M1a is concave and lower than the upper surface SBa. However, the present disclosure is not limited to the above. In other embodiments, the upper surface M1a of the conductive layer M1 may be aligned with the upper surface SBa of the substrate SB (as shown in example (I) of FIG. 8, wherein the first height difference D1 is 0), or in yet other embodiments, the upper surface M1a of the conductive layer M1 may protrude relative to the upper surface SBa of the substrate SB, forming a protrusion such that the upper surface M1a is convex and higher than the upper surface SBa (as shown in example (III) of FIG. 8). Similar to the above upper surface M1a of the conductive layer M1, in the direction Y, the maximum height difference between the lower surface SBb of the substrate SB and the lower surface M1b of the conductive layer M1 may be less than or equal to 1 micrometer, wherein the lower surface M1b of the conductive layer M1 may be recessed, protruding, or aligned relative to the lower surface SBb of the substrate SB, which will not be redundantly described herein.

According to the embodiment shown in FIG. 3, the first protective layer PL1 has an upper surface PLa (which may be referred to as a fourth surface) and a lower surface PLb opposite to the upper surface PLa after the portion of the first protective layer PL1 is removed through the thinning step (i.e., Step S500), wherein the upper surface PLa is adjacent to the upper surface SBa of the substrate SB, and the lower surface PLb is adjacent to the lower surface SBb of the substrate SB. The upper surface PLa and the lower surface PLb of the first protective layer PL1 may be recessed relative to the upper surface SBa and the lower surface SBb of the substrate SB, respectively, thereby forming a spacing SP between the side wall VHS of the through hole VH and the second protective layer PL2. In the direction Y, the maximum height difference between the upper surface SBa of the substrate SB and the upper surface PLa of the first protective layer PL1 may be defined as a second height difference D2, wherein a ratio of the first height difference D1 to the second height difference D2 may be greater than or equal to 0.8 and less than or equal to 1.2 (i.e., 0.8≤D1/D2≤1.2). Similarly, a ratio of the maximum height difference between the lower surface SBb of the substrate SB and the lower surface M1b of the conductive layer M1 to the maximum height difference between the lower surface SBb of the substrate SB and the lower surface PLb of the first protective layer PL1 may also be greater than or equal to 0.8 and less than or equal to 1.2. In some embodiments, a ratio of the second height difference D2 to a thickness TSB of the substrate SB may be greater than or equal to 0.01 and less than or equal to 0.1 (i.e., 0.01≤D2/TSB≤0.1), wherein the thickness TSB may be obtained by measuring the maximum thickness of the substrate SB in the direction Y.

After Step S500, Step S510 may be performed to carry out an inspection on the substrate SB to obtain a thickness variation value TV of the substrate SB, wherein the thickness variation value TV is less than or equal to 20 micrometers. At least five locations on the substrate SB may be selected, then the thicknesses of the substrate SB at these five locations in the direction Y may be measured, and the variation value of these measured thicknesses may be used as the thickness variation value TV of the substrate SB. Specifically, when values of N thicknesses of the substrate SB are measured (denoted as THi in equation (1), wherein i ranges from 1 to N, and Nis a positive integer), the average value M of these N thicknesses may first be calculated, and the thickness variation value TV may then be calculated using equation (1) below, but not limited herein.

$$TV = \frac{1}{N} {\sum }_{i = 1}^{N} {( THi - M )}^{2} \qquad ( 1 )$$

As shown in FIG. 4, after performing the thinning step (i.e., Step S500) or inspecting the substrate SB (i.e., Step S510), Step S600 may further be performed to form a circuit structure CST on a side of the substrate SB, which may include the following steps:

Step S610: forming an insulating layer on the substrate, and forming an opening in the insulating layer to expose the conductive layer; and

Step S620: forming a conductive pattern layer in the opening and on the insulating layer.

Specifically, as shown in FIG. 4, after Step S500 or Step S510, Step S610 may be performed to respectively form an insulating layer IL on the upper surface SBa and the lower surface SBb of the substrate SB, and a portion of the insulating layer IL may be filled in the spacing SP (shown in FIG. 3) between the side wall VHS of the through hole VH and the second protective layer PL2, so as to enhance the adhesion between layers. Furthermore, one or more openings HO may be formed in the insulating layer IL to expose the upper surface M1a and the lower surface M1b of the conductive layer M1. The material of the insulating layer IL may include, for example, polyimide, photosensitive polyimide, Ajinomoto Build-up Film (ABF), silicon oxide (SiOx), silicon nitride (SiNx), silicon oxide nitride (SiOxNy) or other suitable dielectric materials.

After Step S610, Step S620 may be performed to form a conductive pattern layer CL in the openings HO and on the insulating layer IL. The material of the conductive pattern layer CL may include, for example, copper (Cu), titanium (Ti), aluminum (Al), molybdenum (Mo), nickel (Ni), ruthenium (Ru), tantalum (Ta), tungsten (W), other suitable conductive materials or combinations of the above materials. According to the embodiment shown in FIG. 4, before forming the conductive pattern layer CL, a seed layer CL0 may first be formed on the upper surface M1a and the lower surface M1b of the conductive layer M1, the side walls of the openings HO and a portion of the surface of the insulating layer IL, and then the conductive pattern layer CL may be formed on the seed layer CL0, thereby forming a connection stack structure CNS as shown in FIG. 4. The connection stack structure CNS may be applied in an electronic device as a portion of a layer-stacking structure of the electronic device. The seed layer CL0 may facilitate the formation of the conductive pattern layer CL and/or enhance the adhesion between layers. The seed layer CL0 may be a single-layer or multi-layer structure, and the material of the seed layer CL0 may be referred to the aforementioned seed layer M0, which will not be redundantly described herein. In some embodiments, as shown in FIG. 4, the insulating layer IL, the seed layer CL0 and the conductive pattern layer CL may together form the circuit structure CST. Alternatively, in other embodiments, the insulating layer IL, the seed layer CL0 and the conductive pattern layer CL may be used to form a portion of the circuit structure CST of an electronic device (as shown in FIG. 5). The circuit structure CST may be electrically connected to a chip or an electronic unit through bonding pads or other bonding elements.

In some embodiments, after forming the connection stack structure CNS as shown in FIG. 4, the connection stack structure CNS may further be inspected to determine whether the connection stack structure CNS, or specifically the circuit structure CST therein, is a qualified product. After forming or inspecting the connection stack structure CNS, a cutting process may optionally be performed on the connection stack structure CNS, for example, by cutting along a cutting line CTL. The cutting process may include, for example, laser cutting, blade cutting, other suitable processes or any combination of the above. In some embodiments, the cutting process may include first cutting the portion of the insulating layer IL in the circuit structure CST corresponding to the cutting line CTL, and then cutting the substrate SB along the cutting line CTL, thereby obtaining a plurality of separated connection stack units. In some embodiments, after the above cutting process, the connection stack units may further be inspected to determine whether they are qualified products, but not limited herein.

The electronic device (or the connection stack structure CNS of the electronic device) manufactured by the method illustrated in FIG. 2 to FIG. 4 may include a substrate SB, a first protective layer PL1 and a conductive layer M1. The substrate SB has an upper surface SBa, a lower surface SBb and one or more through holes VH, wherein the side wall VHS of the through hole VH is connected with the upper surface SBa and the lower surface SBb. The first protective layer PL1 is disposed on the side wall VHS of the through hole VH, and the conductive layer M1 is disposed in the through hole VH. The thickness variation value TV of the substrate SB is less than or equal to 20 micrometers. According to the embodiment shown in FIG. 4, the manufactured electronic device may further include a second protective layer PL2, a third protective layer PL3, and a circuit structure CST composed of an insulating layer IL, a seed layer CL0 and a conductive pattern layer CL. The detailed structures and materials of the layers and components of the electronic device described above may be referred to the aforementioned embodiments and will not be redundantly described herein.

According to the manufacturing method of the electronic device and the manufactured connection stack structure CNS of the electronic device described in the above embodiments, by forming the first protective layer PL1 on the side wall VHS of the through hole VH in the substrate SB during the process, and further forming the second protective layer PL2 and the third protective layer PL3, the stress matching problem between layers may be alleviated, thereby reducing the probability of substrate SB cracking or layer delamination when the conductive pattern layer CL is subsequently formed or when the circuits are subsequently formed on the conductive pattern layer CL, so that the yield and reliability of the electronic device is improved. Furthermore, according to the layer-stacking structure design described above, the thickness variation value TV of the substrate SB may be made less than or equal to 20 micrometers, thereby improving the surface flatness of the substrate SB.

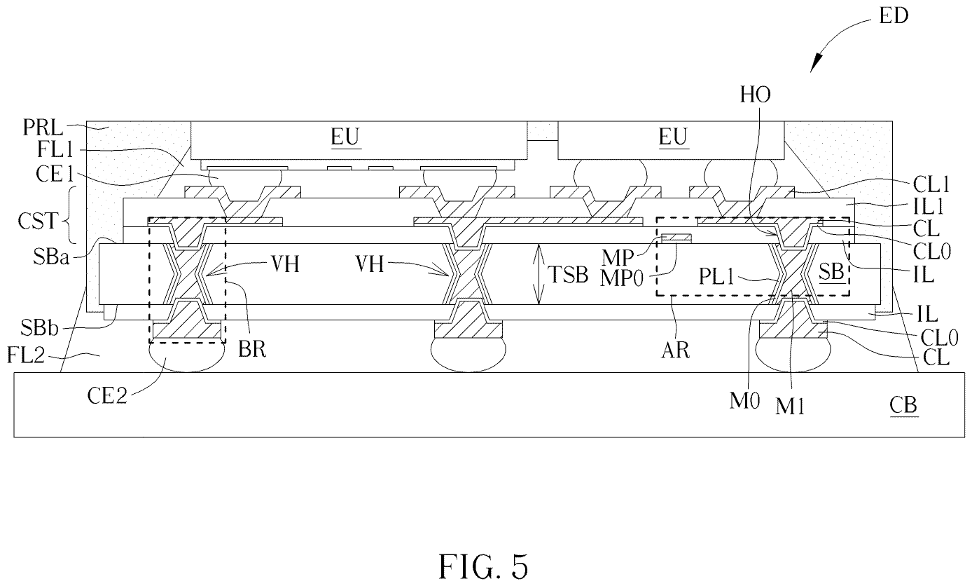

Please refer to FIG. 5 and FIG. 6. FIG. 5 is a cross-sectional schematic diagram of an electronic device according to an embodiment of the present disclosure. FIG. 6 is an enlarged cross-sectional schematic diagram of a region AR shown in FIG. 5, wherein in order to simplify the illustration, the insulating layer IL1 is omitted in FIG. 6. The manufacturing process of a region BR in the electronic device ED shown in FIG. 5 may correspond to the above manufacturing method shown in FIG. 2 to FIG. 4, but not limited herein. The electronic device ED shown in FIG. 5 is merely an example, and the structure of the electronic device of the present disclosure is not limited herein. In some embodiments, within each through hole VH of the substrate SB, the second protective layer PL2 and/or the third protective layer PL3 may be disposed between the seed layer M0 and the first protective layer PL1 (as shown in FIG. 4). As shown in FIG. 5 and FIG. 6, the insulating layer IL, the seed layer CL0 and the conductive pattern layer CL disposed on the substrate SB may be used to form a portion of the circuit structure CST of the electronic device ED. Specifically, the circuit structure CST may be disposed on one side of the substrate SB, for example, on the upper surface SBa of the substrate SB. The insulating layer IL may be disposed on the upper surface SBa of the substrate SB and have one or more openings HO, and the opening HO exposes the conductive layer M1. The conductive pattern layer CL may be disposed in the opening HO and on the insulating layer IL. As shown in FIG. 6, in the direction X, a ratio of a bottom width Wb of the conductive pattern layer CL to a top width Wt of the conductive layer M1 may be greater than or equal to 0.5 and less than or equal to 1.2 (i.e., 0.5≤Wb/Wt≤1.2), or may be greater than or equal to 0.6 and less than or equal to 1.0. In the cross-sectional view shown in FIG. 6, the bottom width Wb may be obtained by measuring the width of the bottom surface of the conductive pattern layer CL closest to the conductive layer M1 in the direction X, and the top width Wt may be obtained by measuring the width of the top surface of the conductive layer M1 closest to the conductive pattern layer CL in the direction X.

According to the embodiment shown in FIG. 6, a surface roughness of the insulating layer IL may be greater than a surface roughness of the substrate SB, and a surface roughness of the conductive pattern layer CL may be greater than the surface roughness of the substrate SB. The surface roughness of the substrate SB may be less than or equal to 1.5 micrometers. The insulating layer IL may include a plurality of particles ILP, and the plurality of particles ILP may have different particle sizes. In the direction Y, the maximum height difference between the upper surface SBa of the substrate SB and the upper surface M1a of the conductive layer M1 may be defined as a first height difference D1, wherein the first height difference D1 is less than or equal to 1 micrometer. In the direction Y, the maximum height difference between the upper surface SBa of the substrate SB and the upper surface PLa of the first protective layer PL1 may be defined as a second height difference D2, wherein the ratio of the first height difference D1 to the second height difference D2 may be greater than or equal to 0.8 and less than or equal to 1.2. In some embodiments, the ratio of the second height difference D2 to the thickness TSB of the substrate SB in the direction Y (as shown in FIG. 5) may be greater than or equal to 0.01 and less than or equal to 0.1.

According to the embodiment shown in FIG. 5, the circuit structure CST may include at least one conductive layer (e.g., the conductive pattern layer CL and one or more conductive layers CL1) and at least one insulating layer (e.g., the insulating layer IL and one or more insulating layers IL1). The conductive layer M1, the conductive pattern layer CL and the conductive layers CL1 may be electrically connected in the stacking direction through the openings HO in the insulating layer IL and the openings in each insulating layer IL1, wherein the stacking direction may be the direction Y. The conductive layer CL1 farthest from the substrate SB may include a plurality of connection pads for bonding with the electronic unit EU or other suitable components. One or more electronic units EU may be disposed on the circuit structure CST and bonded to the circuit structure CST through bonding elements CE1, such that the electronic unit EU may be electrically connected to other components through the conductive layers CL1, the conductive pattern layer CL and the conductive layer M1 in the through holes VH of the substrate SB. For example, the electronic unit EU may be further electrically connected to a circuit board CB through bonding elements CE2 disposed on a side of the substrate SB opposite to the circuit structure CST. The circuit structure CST may serve as a redistribution structure to redistribute the circuits and/or increase the fan-out area of the circuitry, or different electronic units EU may be electrically connected to each other through the circuit structure CST.

In some embodiments, as shown in FIG. 5 and FIG. 6, the circuit structure CST may further include a metal pattern MP and a seed layer MP0 disposed beneath the metal pattern MP. The seed layer MP0 may be disposed between the metal pattern MP and the substrate SB, and the insulating layer IL may surround both the seed layer MP0 and the metal pattern MP. A ratio of a width W1 of the metal pattern MP to a width W2 of the seed layer MP0 in the direction X may be greater than or equal to 1.01 and less than or equal to 1.2 (i.e., 1.01≤W1/W2≤1.2), so that the adhesion of the insulating layer IL surrounding the seed layer MP0 and the metal pattern MP may be increased.

The bonding elements CE1 and the bonding elements CE2 may include, for example, solder balls, nickel, gold, copper, gallium or other suitable conductive materials. The material of the insulating layer IL1 may be referred to the material of the insulating layer IL described above, the materials of the conductive layer CL1 and the metal pattern MP may be referred to the material of the conductive pattern layer CL described above, and the material of the seed layer MP0 may be referred to the material of the seed layer M0 described above, which will not be redundantly described herein. In some embodiments, according to the electronic device ED shown in FIG. 5, the seed layer M0, the seed layer MP0 and the seed layer CL0 may each be formed from a first conductive layer that includes a seed layer, and the conductive layer M1, the metal pattern MP and the conductive layer CL1 may each be formed from a second conductive layer, wherein the first conductive layer facilitates the formation of the second conductive layer, but not limited herein.

According to the embodiment shown in FIG. 5, the electronic device ED may further include an encapsulation layer PRL that surrounds the substrate SB, the circuit structure CST and the electronic units EU, serving to block moisture, air and/or reduce damage to the electronic units EU. The encapsulation layer PRL may include organic resin, epoxy resin, epoxy molding compound (EMC), ceramic, poly(methyl methacrylate) (PMMA), polydimethylsiloxane (PDMS), other suitable materials or combinations of the above materials, but not limited herein. In some embodiments, the electronic device ED may further include a filling layer FL1 and a filling layer FL2. The filling layer FL1 may be disposed between the electronic unit EU and the circuit structure CST to surround and protect the bonding elements CE1, and the filling layer FL2 may be disposed between the substrate SB and the circuit board CB to surround and protect the bonding elements CE2 and may serve as a buffer layer, but not limited herein.

Some embodiments of the manufacturing method of the electronic device and the manufactured layer-stacking structures of the electronic devices of the present disclosure will be detailed in the following. In order to simplify the illustration, the same elements in the following would be labeled with the same symbols. The differences between different embodiments are described in detail below, and the same features would not be described redundantly.

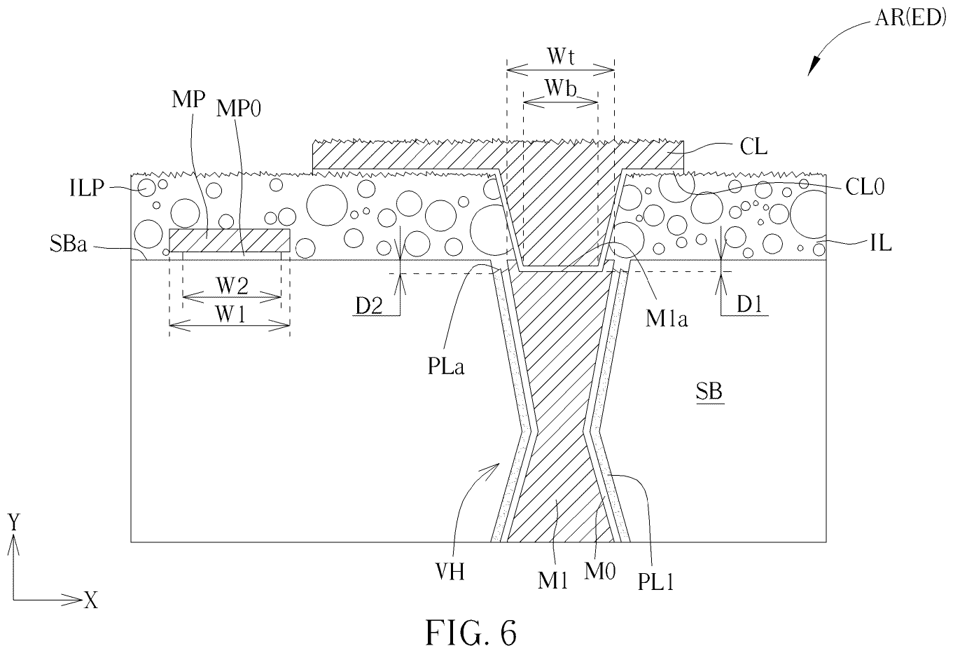

Please refer to FIG. 7 and FIG. 8. FIG. 7 is a schematic diagram illustrating a portion of the process of a manufacturing method of an electronic device according to a second embodiment of the present disclosure, wherein FIG. 7 illustrates a layer-stacking structure after performing Step S610 of forming the insulating layer IL and before performing Step S620 of forming the conductive pattern layer CL. FIG. 8 is an enlarged schematic diagram of some variant embodiments of a region CR shown in FIG. 7. The manufacturing method of the electronic device of the second embodiment shown in FIG. 7 differs from that of the first embodiment shown in FIG. 4 in that the shape of each of the plurality of through holes VH penetrating through the substrate SB is rectangular, the upper surface PLa and the lower surface PLb of the first protective layer PL1 may be aligned with the upper surface SBa and the lower surface SBb of the substrate SB, respectively, and each corner SBC of the substrate SB may be arc corner. Furthermore, as shown in FIG. 7 and example (I) of FIG. 8, the upper surface M1a of the conductive layer M1 may be aligned with the upper surface SBa of the substrate SB, that is, the maximum height difference between the upper surface SBa and the upper surface M1a in the direction Y (i.e., the first height difference D1 described in the first embodiment) is zero. However, the present disclosure is not limited thereto. In another embodiment, as shown in example (II) of FIG. 8, the upper surface M1a of the conductive layer M1 may be recessed relative to the upper surface SBa of the substrate SB, forming a recess such that the upper surface M1a is concave and lower than the upper surface SBa. In yet another embodiment, as shown in example (III) of FIG. 8, the upper surface M1a of the conductive layer M1 may protrude relative to the upper surface SBa of the substrate SB, forming a protrusion such that the upper surface M1a is convex and higher than the upper surface SBa. According to example (II) and example (III) shown in FIG. 8, the maximum height difference between the upper surface SBa of the substrate SB and the upper surface M1a of the conductive layer M1 in the direction Y may be defined as the first height difference D1, wherein the first height difference D1 is less than or equal to 1 micrometer.

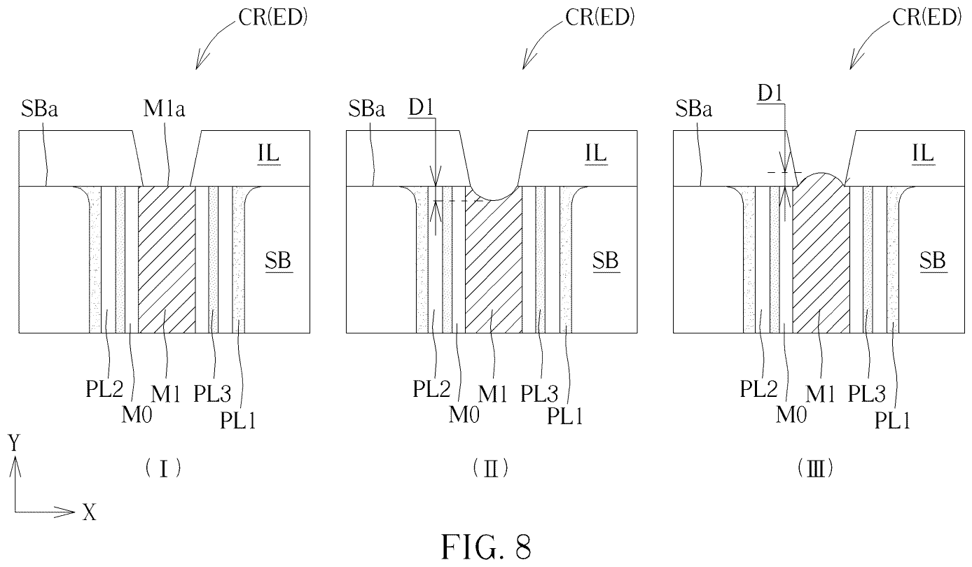

Please refer to FIG. 9, which is a schematic diagram illustrating a portion of the process of a manufacturing method of an electronic device according to a third embodiment of the present disclosure, wherein FIG. 9 illustrates a layer-stacking structure after performing Step S610 of forming the insulating layer IL and before performing Step S620 of forming the conductive pattern layer CL. According to the embodiment shown in FIG. 9, the first protective layer PL1 may cover only a portion of the side wall VHS of the through hole VH adjacent to the upper surface SBa and lower surface SBb of the substrate SB, and the second protective layer PL2 may cover another portion of the side wall VHS of the through hole VH. That is to say, the first protective layer PL1 may be formed on the portion of the side wall VHS near the corners where the side wall VHS is connected with the upper surface SBa and lower surface SBb. Since stress mismatch tends to occur at the corner where the side wall VHS of the through hole VH is connected with the upper surface SBa or lower surface SBb of the substrate SB, forming the first protective layer PL1 in this region may reduce the probability of substrate cracking. In some embodiments, the first protective layer PL1 may cover at least one-third of the side wall VHS. In some embodiments, as shown in FIG. 9, each corner SBC of the substrate SB may have a chamfer, but not limited herein.

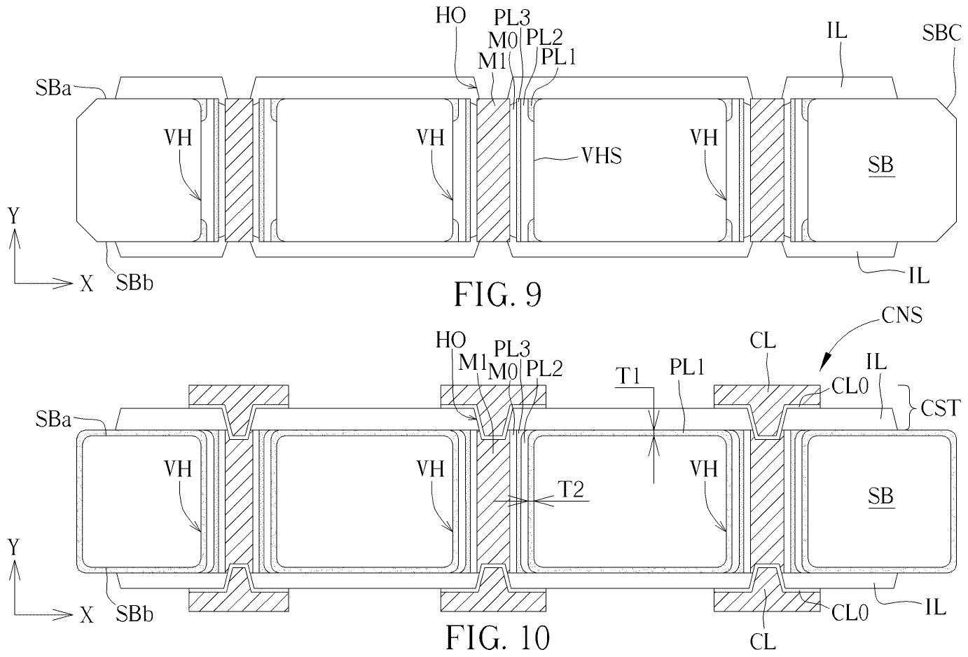

Please refer to FIG. 10, which is a schematic diagram illustrating a portion of the process of a manufacturing method of an electronic device according to a fourth embodiment of the present disclosure, wherein FIG. 10 illustrates the layer-stacking structure (i.e., the connection stack structure CNS) after performing Step S620 of forming the conductive pattern layer CL. According to the embodiment shown in FIG. 10, the first protective layer PL1 may cover the side wall VHS of each through hole VH as well as the upper surface SBa and the lower surface SBb of the substrate SB. The first protective layer PL1 may have a first thickness T1 on the upper surface SBa (or the lower surface SBb) and a second thickness T2 on the side wall VHS, wherein a ratio of the second thickness T2 to the first thickness T1 may be greater than or equal to 0.001 and less than or equal to 0.15 (i.e., 0.001≤T2/T1≤0.15). In some embodiments, the first thickness T1 may be greater than or equal to 2 micrometers and less than or equal to 10 micrometers, but not limited herein.

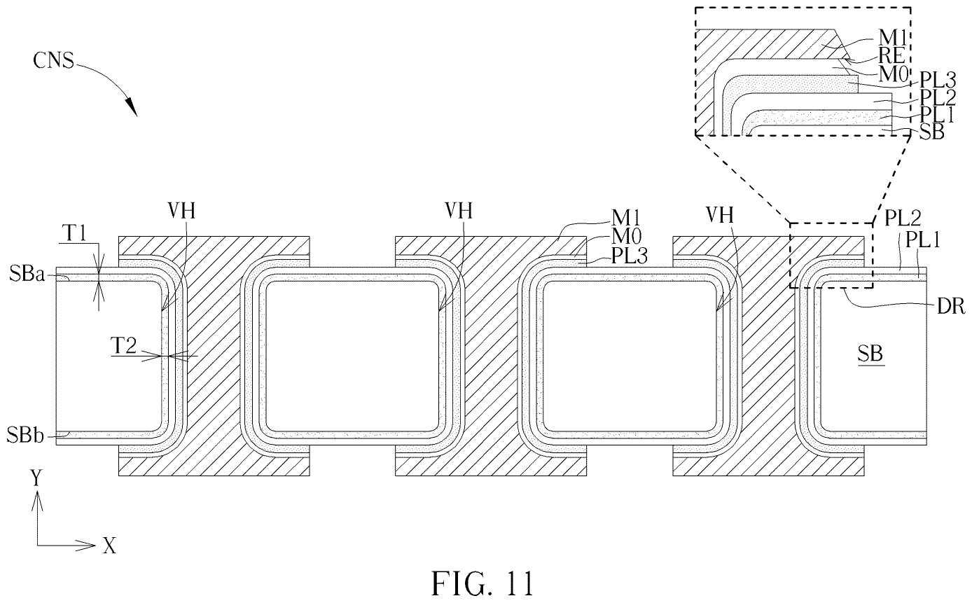

Please refer to FIG. 11, which is a schematic diagram illustrating a portion of the process of a manufacturing method of an electronic device according to a fifth embodiment of the present disclosure, wherein the upper-right portion of FIG. 11 shows an enlarged schematic diagram of a region DR in the lower cross-sectional view. According to the embodiment shown in FIG. 11, during the thinning step (i.e., Step S500), a portion of the conductive layer M1, a portion of the seed layer M0 and a portion of the third protective layer PL3 may be removed to expose a portion of the second protective layer PL2 located on the upper surface SBa and the lower surface SBb of the substrate SB, thereby forming the connection stack structure CNS shown in FIG. 11, which may be applied in an electronic device as a portion of the layer-stacking structure of the electronic device. Due to differences in etching rates between materials and/or the use of different etching solutions, a recess RE may be formed at the interface between the seed layer M0 and the conductive layer M1 after the above thinning step, and the insulating layer formed on the conductive layer M1 may be filled in the recess RE, which helps enhance the adhesion between layers. In some embodiments, the recess depth of the recess RE in the direction X may be less than or equal to 5 micrometers, or a ratio of this recess depth to the thickness of the substrate SB may range from 0.002 to 0.02, thereby reducing the probability of layer delamination, but not limited herein.

As shown in FIG. 11, the first protective layer PL1 may cover the side wall VHS of each through hole VH as well as the upper surface SBa and the lower surface SBb of the substrate SB, and the second protective layer PL2 may completely cover the first protective layer PL1. The first protective layer PL1 may have a first thickness T1 on the upper surface SBa (or the lower surface SBb) and a second thickness T2 on the side wall VHS, wherein the ratio of the second thickness T2 to the first thickness T1 may be greater than or equal to 0.001 and less than or equal to 0.15 (i.e., 0.001≤T2/T1≤0.15). The thickness of the second protective layer PL2 may be, for example, greater than or equal to 0.1 micrometers and less than or equal to 5 micrometers.

From the above description, according to the manufacturing method of the electronic device and the manufactured electronic device of the embodiments of the present disclosure, by forming the first protective layer on the side wall of the through hole in the substrate during the manufacturing process, and further forming the second protective layer and the third protective layer, the stress matching problem between layers may be alleviated, thereby enhancing the yield and reliability of the electronic device. Furthermore, according to the layer-stacking structure design of the electronic device of the present disclosure, the thickness variation value of the substrate may be made less than or equal to 20 micrometers, thereby improving the surface flatness of the substrate SB. In addition, during the manufacturing process, the first thickness of the first protective layer on the upper surface or the lower surface of the substrate may be measured and controlled to ensure that the second thickness of the first protective layer on the side wall of the through hole meets the required standard.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A manufacturing method of an electronic device, comprising:
providing a substrate, wherein the substrate has a first surface and a second surface opposite to the first surface;
forming a through hole penetrating the substrate, wherein a side wall of the through hole is connected with the first surface and the second surface;
forming a first protective layer on the first surface, the second surface and the side wall;
forming a conductive layer on the first protective layer such that a portion of the conductive layer is disposed in the through hole;
performing a thinning step to remove another portion of the conductive layer; and
performing an inspection on the substrate to obtain a thickness variation value of the substrate, wherein the thickness variation value is less than or equal to 20 micrometers.

2. The manufacturing method of the electronic device according to claim 1, further comprising inspecting a first thickness of the first protective layer on the first surface and a second thickness of the first protective layer on the side wall after forming the first protective layer, wherein the step of forming the conductive layer is performed when a ratio of the second thickness to the first thickness is greater than or equal to 0.001 and less than or equal to 0.15.

3. The manufacturing method of the electronic device according to claim 1, wherein the first protective layer comprises at least one of an organic material and an inorganic material.

4. The manufacturing method of the electronic device according to claim 1, further comprising forming a second protective layer on the first protective layer before forming the conductive layer.

5. The manufacturing method of the electronic device according to claim 4, wherein a dissipation factor of the second protective layer is less than a dissipation factor of the first protective layer.

6. The manufacturing method of the electronic device according to claim 4, further comprising forming a third protective layer on the second protective layer after forming the second protective layer.

7. The manufacturing method of the electronic device according to claim 1, wherein the conductive layer has a third surface adjacent to the first surface after the another portion of the conductive layer is removed, and a maximum height difference between the first surface and the third surface in a normal direction of the substrate is defined as a first height difference, wherein the first height difference is less than or equal to 1 micrometer.

8. The manufacturing method of the electronic device according to claim 7, wherein the thinning step further comprises removing a portion of the first protective layer.

9. The manufacturing method of the electronic device according to claim 8, wherein the first protective layer has a fourth surface adjacent to the first surface after the portion of the first protective layer is removed, and a maximum height difference between the first surface and the fourth surface in the normal direction is defined as a second height difference, wherein a ratio of the first height difference to the second height difference is greater than or equal to 0.8 and less than or equal to 1.2.

10. The manufacturing method of the electronic device according to claim 9, wherein a ratio of the second height difference to a thickness of the substrate is greater than or equal to 0.01 and less than or equal to 0.1.

11. The manufacturing method of the electronic device according to claim 1, wherein after performing the thinning step, the manufacturing method of the electronic device further comprises:
forming an insulating layer on the substrate, and forming an opening in the insulating layer to expose the conductive layer; and
forming a conductive pattern layer in the opening and on the insulating layer.

12. A manufacturing method of an electronic device, comprising:
providing a substrate, wherein the substrate has a first surface and a second surface opposite to the first surface;
forming a through hole penetrating the substrate, wherein a side wall of the through hole is connected with the first surface and the second surface;
forming a first protective layer on the first surface, the second surface and the side wall;
inspecting a first thickness of the first protective layer on the first surface and a second thickness of the first protective layer on the side wall, and determining whether a ratio of the second thickness to the first thickness is greater than or equal to 0.001 and less than or equal to 0.15;
forming a conductive layer on the first protective layer such that a portion of the conductive layer is disposed in the through hole; and
performing a thinning step to remove another portion of the conductive layer.

13. An electronic device, comprising:
a substrate having a first surface, a second surface and a through hole, wherein a side wall of the through hole is connected with the first surface and the second surface;
a first protective layer disposed on the side wall of the through hole; and
a conductive layer disposed in the through hole,
wherein a thickness variation value of the substrate is less than or equal to 20 micrometers.

14. The electronic device according to claim 13, wherein the first protective layer has a first thickness on the first surface and a second thickness on the side wall, and a ratio of the second thickness to the first thickness is greater than or equal to 0.001 and less than or equal to 0.15.

15. The electronic device according to claim 13, wherein the conductive layer has a third surface adjacent to the first surface, and a maximum height difference between the first surface and the third surface in a normal direction of the substrate is defined as a first height difference, wherein the first height difference is less than or equal to 1 micrometer.

16. The electronic device according to claim 15, wherein the first protective layer has a fourth surface adjacent to the first surface, and a maximum height difference between the first surface and the fourth surface in the normal direction is defined as a second height difference, wherein a ratio of the first height difference to the second height difference is greater than or equal to 0.8 and less than or equal to 1.2.

17. The electronic device according to claim 13, further comprising a circuit structure disposed on a side of the substrate, wherein the circuit structure comprises:
an insulating layer disposed on the substrate and having an opening, wherein the opening exposes the conductive layer; and
a conductive pattern layer disposed in the opening and on the insulating layer, wherein a ratio of a bottom width of the conductive pattern layer to a top width of the conductive layer is greater than or equal to 0.5 and less than or equal to 1.2.

18. The electronic device according to claim 17, wherein a surface roughness of the insulating layer is greater than a surface roughness of the substrate, and a surface roughness of the conductive pattern layer is greater than the surface roughness of the substrate.

19. The electronic device according to claim 13, further comprising a second protective layer disposed on a surface of the first protective layer, wherein a thickness of the second protective layer is greater than or equal to 0.1 micrometers and less than or equal to 5 micrometers.

20. The electronic device according to claim 19, wherein the first protective layer covers a portion of the side wall adjacent to the first surface and the second surface, and the second protective layer covers another portion of the side wall.
